(19) United States
(12) Patent Application Publication
(10) Pub. No.: US 2016/0095252 A1
(43) Pub. Date: Mar. 31, 2016

(54) VERTICAL ELECTRONIC DEVICE WITH CURVED TOP SURFACE DESIGN

(71) Applicant: THOMSON LICENSING, Issy de Moulineaux (FR)

(72) Inventor: William P. Dernier, Indianapolis, IN (US)

(21) Appl. No.: 14/864,794

(22) Filed: Sep. 24, 2015

Related U.S. Application Data
(60) Provisional application No. 62/055,235, filed on Sep. 25, 2014.

(51) Int. Cl. H05K 7/20; H05K 5/00

(52) U.S. Cl. CPC H05K 7/20209; H05K 5/0004

(57) ABSTRACT

A housing for an electronic device is provided that includes a curved top; a vertical front wall; a vertical rear wall; vertical side walls; at least one electronic component in the housing generating heat during operation; and, a thermal management system for dissipating the heat. The thermal management system can include at least one of active and passive components. The thermal management system can include in at least one of the vertical walls or in each of the vertical side walls.

### CROSS-REFERENCE TO RELATED APPLICATIONS

This application claims the benefit of U.S. Provisional Application Ser. No. 62/055,235, filed Sep. 25, 2014, which is incorporated by reference herein in its entirety.

### FIELD OF THE INVENTION

The present invention relates to an electronic apparatus and an associated top surface design thereof.

### BACKGROUND

Electronic apparatuses or devices such as set top boxes are typically assembled apparatuses having a plurality of walls and a top surface that is generally designed to encase and protect interior components. Most designs of these electronic apparatuses are such that the top plan view shape is rectangular and the apparatuses are horizontal electronic apparatuses in which the height of the apparatuses is smaller than the horizontal widths of the front wall, rear wall, and the sides walls. Such horizontal devices are mechanically stable given their wide bases and their tops being planar horizontal structures.

Given that horizontal devices are mechanically stable with flat tops, their tops can be inviting stable surfaces for people to place objects thereon (such as papers, tools, cups with liquids, and other liquid filled vessels such as vases or potted plants). Although the manufacturers may not encourage the use of the top surfaces for supporting objects, the use of such top surfaces is generally mechanically safe in terms of providing a large flat surface area that will not cause the objects to fall.

New vertical electronic apparatuses are now being contemplated for the consumer market in which the height of the apparatuses is larger than the horizontal widths of at least one of the walls. FIG. 1 shows a perspective view of a considered vertically oriented electronic device 200 having a flat top 210, a front wall or front surface 208, a rear wall 206, side walls 204, and a base 205. FIG. 2 shows an interior view highlighting the intersections of the flat top 210 with the rear wall 206 and the flat top 210 with a side wall 204 in which the intersections 290 are not smooth and continuous. In fact, the intersections 290 form angles which are 90 degrees.

Unfortunately, the top surfaces or flat tops 210 of such vertical devices can also be inviting for people to place objects thereon. However, for such vertical electronic apparatuses, the placement of the objects thereon is generally not mechanically safe, because (1) such devices have the potential to have high centers of mass and can tip and fall if objects are placed on them, (2) such devices may have access ways that will be covered by objects in a manner that will not only prevent entry, but can cause damage to the entry way and provide an easy entrance way for spilled liquids to enter to the apparatus, and (3) such devices may have heat management systems which may require that the top be free of objects to avoid interfering with heat management systems.

As such, a need exists for a vertical electronic device that has a top surface that discourages the placement of objects thereon.

### SUMMARY

The present principles can include a housing for an electronic device (300) that provides a curved top (310); a vertical front wall (308); a vertical rear wall (306); vertical side walls (304); at least one electronic component (341) in the housing generating heat during operation; and, a thermal management system for dissipating the heat. The thermal management system can include at least one of active and/or passive component. The thermal management system can include vents (320) in at least one of the vertical walls or in each of the vertical side walls. At least one vertical wall can be disposed at an angle, relative to horizontal, such that for any given one of the vents disposed at a lower level than a vent disposed upwardly adjacent to the one of the lower vents in which any of the heat dissipated through any given lower vent is directed upwardly and away from the upwardly adjacent vent. Also, each of the vertical side walls can be disposed at an angle, relative to horizontal, such that for any given one of the vents disposed at a lower level than a vent disposed upwardly adjacent to the one of the lower vents and that any of the heat dissipated through any given lower vent is directed upwardly and away from the upwardly adjacent vent.

The present principles can also be directed to a vertically oriented set top box or gateway device (300) that comprises: a curved top (310); a vertical front wall (308); a vertical rear wall (306); vertical side walls (304); at least one electronic component (341) in the set top box or gateway device generating heat during operation; and, a thermal management system for dissipating the heat. The thermal management system can comprise vents (320) in at least one of the vertical walls and the at least one vertical wall is disposed at an angle, relative to horizontal, such that for any given one of the vents disposed at a lower level than a vent disposed upwardly adjacent to the one of the lower vents and that any of the heat dissipated through the any given lower vent is directed upwardly and away from the upwardly adjacent vent. The thermal management system can also comprise vents in each of the vertical walls and each of the vertical walls is disposed at an angle, relative to horizontal, such that for any given one of the vents disposed at a lower level than a vent disposed upwardly adjacent to the one of the lower vents and that any of the heat dissipated through the any given lower vent is directed upwardly and away from the upwardly adjacent vent. The set top box or gateway device can further include at least one intersection region (312) between the curved top and at least one of the vertical walls that forms an angle or angles greater than 90 degree on an exterior surface of the curved top and the vertical walls. The one intersection region can be along the entire side of one of the vertical walls. An exterior surface of the curved top can be convex and an interior surface of the curved top can be concave. From a top plan view perspective, angles between exterior surfaces of the side vertical walls and the vertical rear wall are acute. A majority of the curved top can be sloped downward toward the vertical front wall.

The present principles can further be directed a vertically oriented set top box (300) comprising: a curved top (310); a vertical front wall (308); a vertical rear wall (306); vertical side walls (304); and at least one heat generating electronic component (341). The vertically oriented set top box can further comprise at least one intersection region (312) between the curved top and at least one of the vertical walls forms an angle or angles greater than 90 degree on an exterior surface of the curved top and the vertical walls. An exterior surface of the curved top can be convex and an interior surface of the curved top can be concave. From a top plan view perspective, angles between exterior surfaces of the side vertical walls and the vertical rear wall are acute. A majority of the curved top can be sloped downward toward the vertical front wall. The vertically oriented set top box can include an access door (314) that is part of the curved top, wherein the access door has an exterior surface that is part of an exterior surface of the curved top. The vertically oriented set top box can includes vents (320) positioned over a majority of plan view surface areas of the side walls.

### BRIEF DESCRIPTION OF THE DRAWINGS

The principles will be explained in greater detail in the following with reference to embodiments, referring to the appended drawings, in which:

FIG. 1 is a perspective view of the vertically oriented electronic device 200 considered for the consumer market;

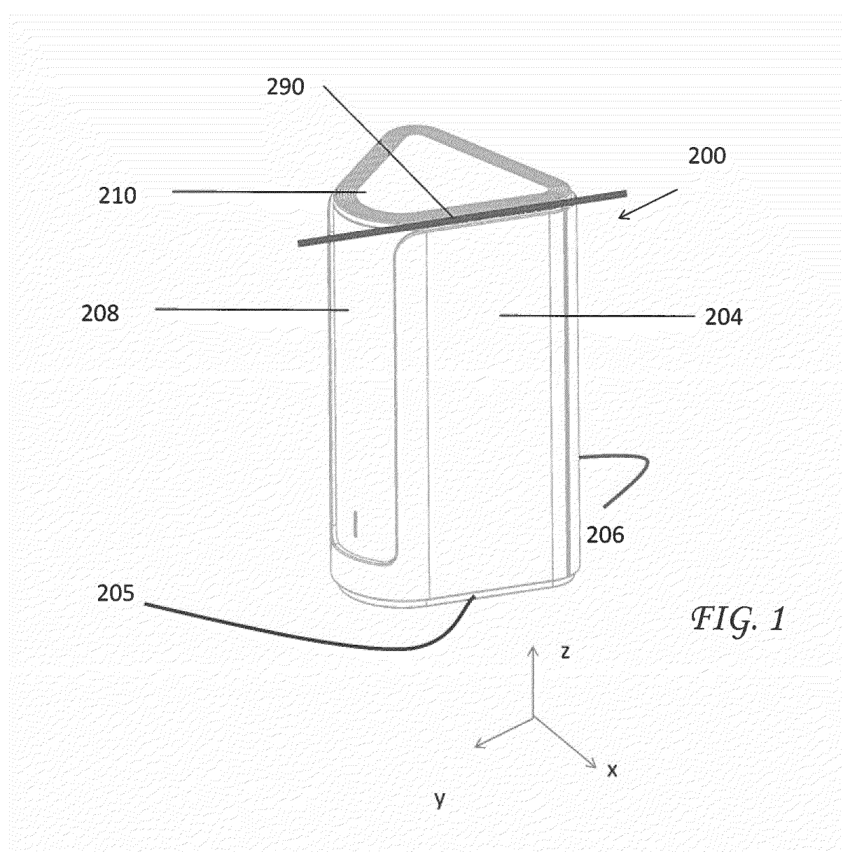

FIG. 2 is an interior perspective view of the vertically oriented electronic device 200 considered for the consumer market;

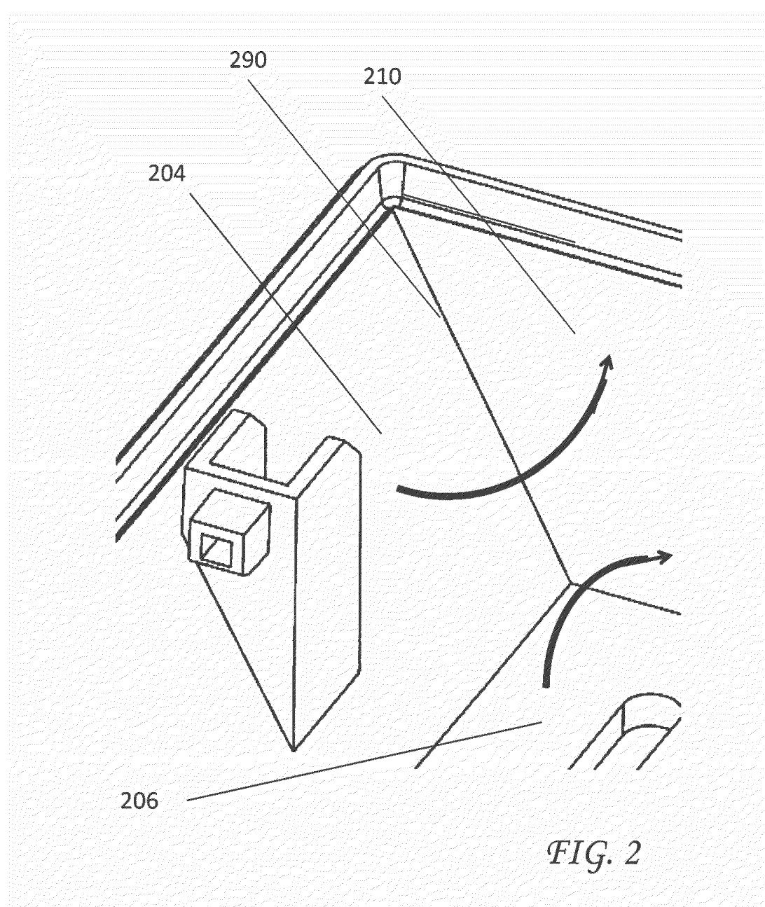

FIG. 3 is a perspective view of the vertically oriented electronic device 300 according to the current principles;

FIG. 4 shows interior sectional views of the vertically oriented electronic device 300 according to the current principles;

FIG. 5 is a top plan view of the vertically oriented electronic device 300 according to the current principles;

FIG. 6 is a front plan view of the vertically oriented electronic device 300 according to the current principles; and

FIG. 7 is a side plan view of the vertically oriented electronic device 300 according to the current principles.

### DETAILED DESCRIPTION OF THE EMBODIMENTS

A vertical electronic device is disclosed that in some embodiments is not rectangular from a top plan view perspective and has a curved top that provides a number of potential benefits. The curved top can provide some additional interior volume for air circulation to assist in heat management. The curved top can also assist in reducing resistance to interior air flow by providing a smoother and more continuous surface at transition locations (e.g. intersection regions) such as where the interior side wall transitions to the interior top wall. The curved top surface which is noticeably curved will discourage people from placing objects thereon, thereby reducing the risk objects being placed on the top surface that can result in damage to top access ways, can interfere with a heat management system, can cause tilting and falling of objects thereon and/or the vertical electronic device, can cause scratches to the top surface, and can cause risk of fluid entry from liquid filled vessels.

The focus of having a curves top surface of the disclosure also fits in line with the consumer demand for more unique and attractive consumer devices.

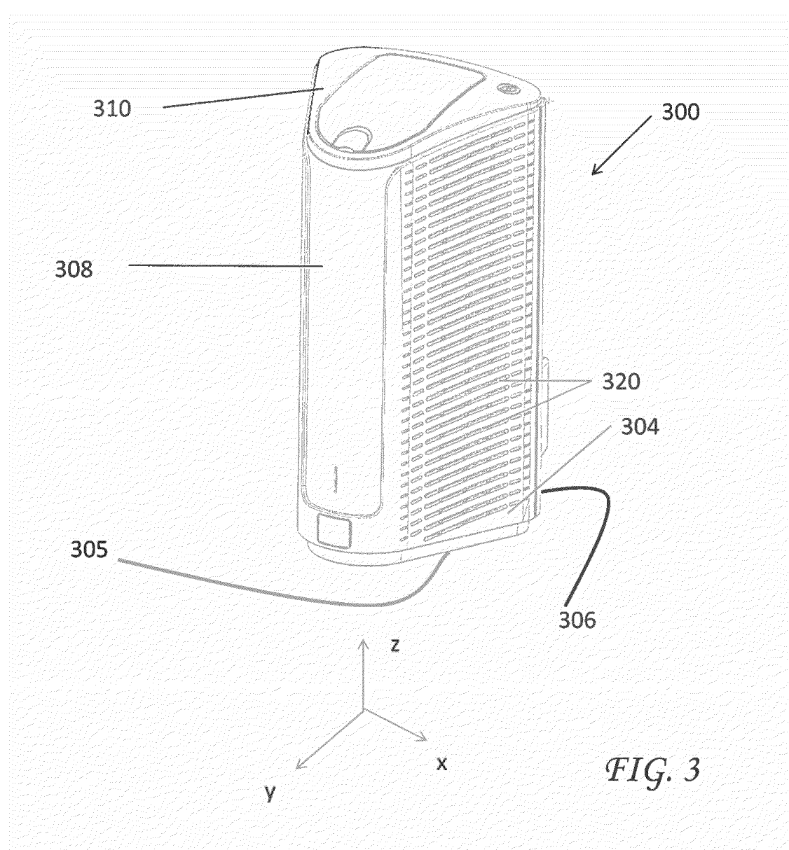

FIG. 3 shows a perspective view of a vertically oriented electronic device 300 according to the current principles. The device 300 has a housing that comprises a curved top 310, a front wall or front surface 308, a rear wall 306, side walls 304, and a base 305.

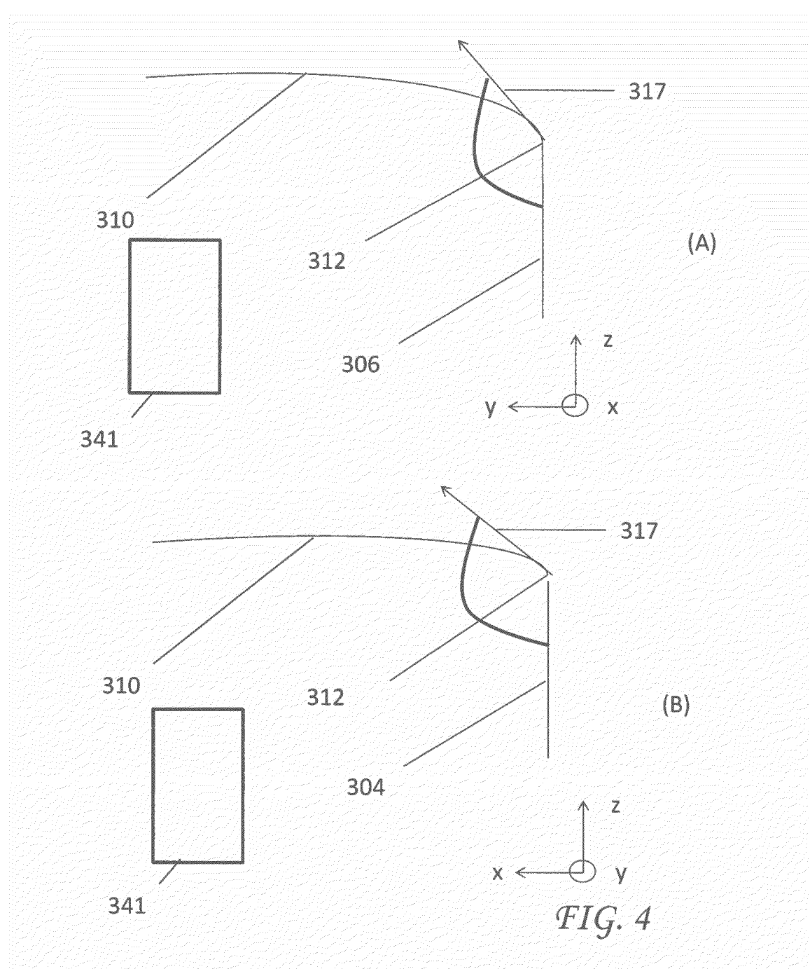

FIG. 4A shows an interior section view highlighting the intersection 312 of the curved top 310 with the rear wall 306. This view shows that the intersection may blend the two surfaces such that the intersection is more smooth and continuous than that of the intersections 290 in device 200 and that an angle between the rear wall and a tangent 317 of the interior surface of the top 310 can be greater than 90 degrees. The intersection 312 may also form a blended radius.

FIG. 4B shows an interior section view highlighting the intersection 312 of the curved top 310 with the side wall 304. This view also shows that the intersection may blend the two surfaces such that the intersection is more smooth and continuous than that to the intersections in device 200 and that an angle between the rear wall and a tangent 317 of the interior surface of the top 310 can be greater than 90 degrees. The intersection 312 may also form a blended radius. It should be noted that the intersection geometry can vary around the periphery of the top 310.

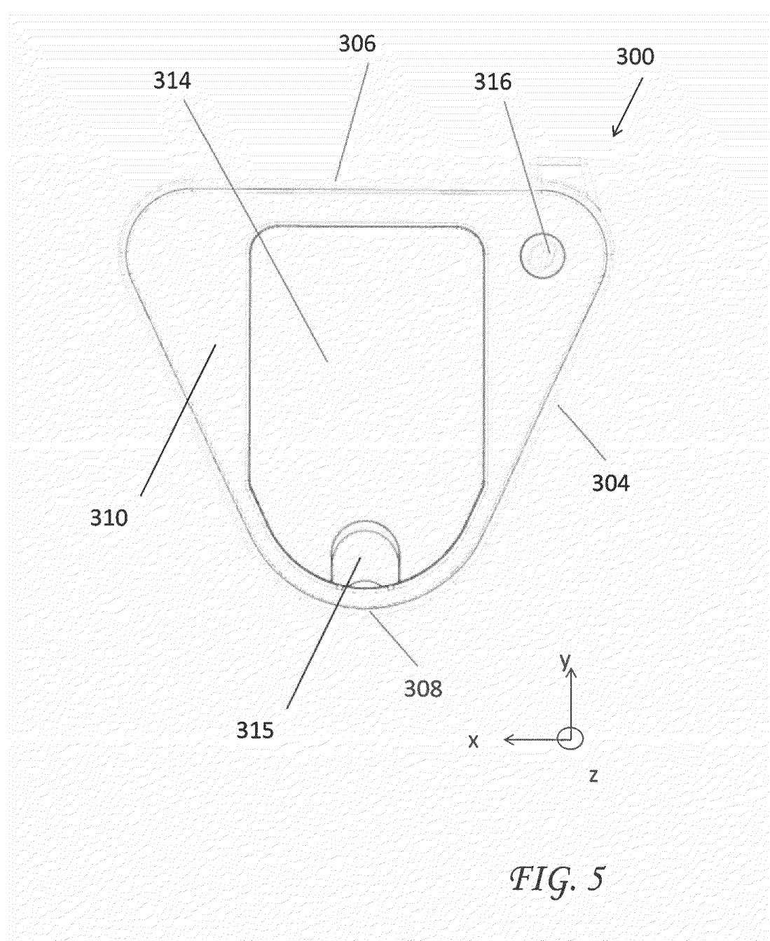

FIG. 5 is a top plan view of the vertically oriented electronic device 300 in which an access door 314 and a power button 316 are shown. This view shows that the access door can have a thumb access slot 315 positioned toward the vertical front surface 308. The hinge for the door 314 can be positioned near vertical rear wall 306. The access door 314 can provide entry for such components as a hard drive/hard drive bay, a smart card/smart card bay, and/or a reset button.

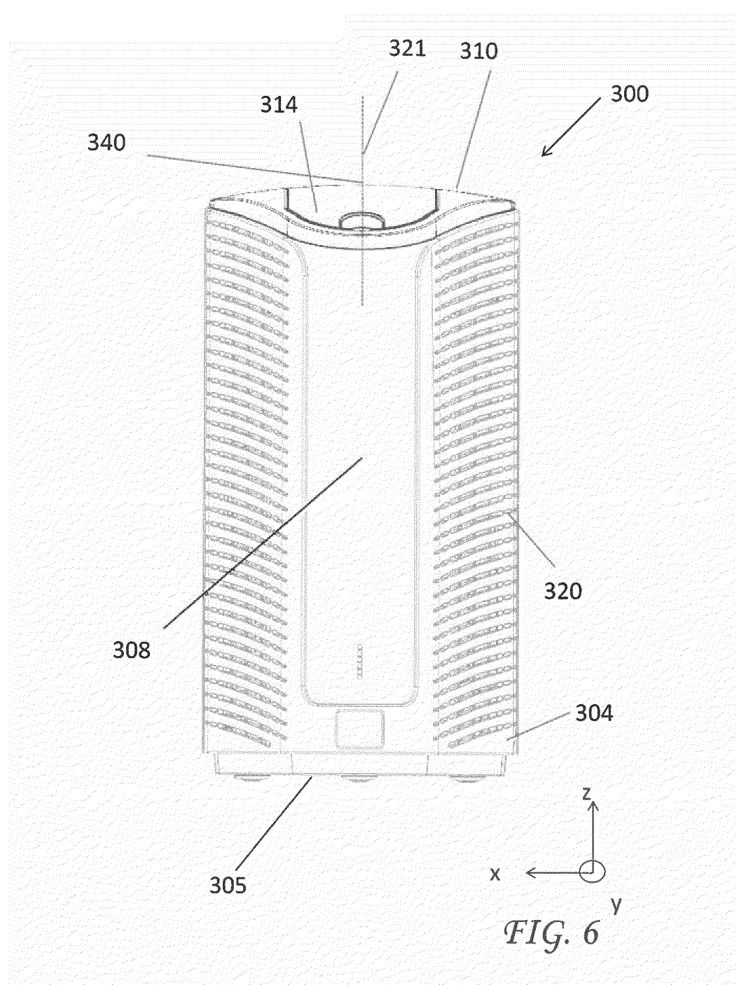

FIG. 6 is a front plan view of the vertically oriented electronic device 300 which shows a series of vents 320 on the side walls 304 which can be part of the heat management system of the device. These vents 320 can be positioned over a majority of the plan view surface area of the side walls and can work with the air circulation character that the curved interior geometry of the curved top which reduces air resistance to permit air to flow more freely past, to and through the vents 320.

This view in FIG. 6 shows that the curvature of the top 310 along the major horizontal x-axis can have an ultimate peak 340 somewhere along the center line 321 of the major axis of the device 300 and that top surface along the center line 321 of the major axis can form a series of peaks with respect to horizontal slices parallel to the x-z plane.

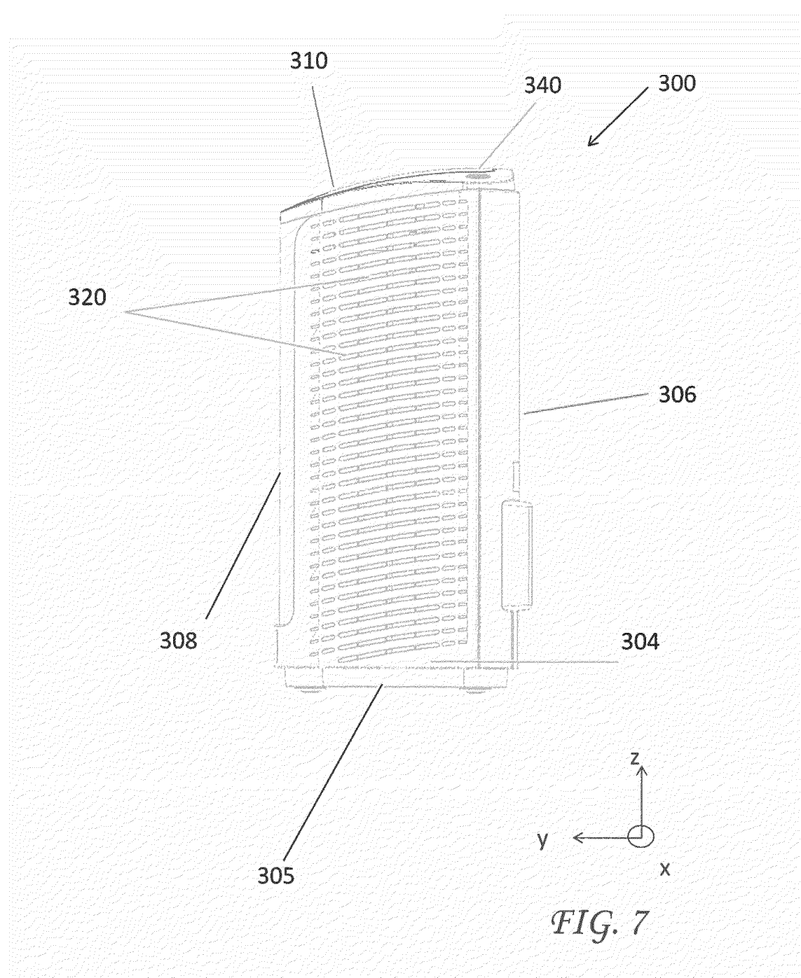

FIG. 7 is a side plan view of the vertically oriented electronic device 300 according to the current principles. This view shows that the curvature of the top 310 along the minor horizontal y-axis can have an ultimate peak 340 along the center line 321 of the major axis of the device 300 and that the ultimate peak 340 is positioned closer to the rear wall 306 than the front surface 308. This ultimate peak 340 in FIG. 7 can be the same ultimate peak shown in FIG. 5.

In sum, the disclosure includes a vertically oriented set top box or electronic device that can have vertical side walls 304 that extend from a vertical rear wall 306. The vertical side walls can narrow as they extend toward a narrow front surface 308. The device further can include a curved top 310 that extends from the vertical side walls 304, the vertical rear wall 306 and the front surface 308. The exterior surface of the top 310 can be convex and have a spherical shape, wherein the exterior top surface can be preferably angled such that all of the exterior top surface to a majority area of the exterior top surface, for example 75%, is tilted or angled downward toward the front surface 308. The exterior top surface of the top 310 can also be convex and have a circular shape along vertical planes parallel to the major axis and/or along vertical planes parallel to the minor axis, wherein the exterior top surface can be preferably angled such that all of the exterior top surface to a majority area of the exterior top surface, for example 75%, is tilted or angled downward toward the front surface 308. The exterior top surface of the top 310 can also be convex and curved along vertical planes parallel to the major axis and/or along vertical planes parallel to the minor axis, wherein the exterior top surface can be angled such that all of the exterior top surface to a majority area of the exterior top surface, for example 75%, is tilted or angled downward toward the front surface 308.

Embodiments of the disclosure can include various combinations of the features thus far described and can further include the features shown in FIG. 4, wherein the interior intersections 312 of the curved top 310 with the rear wall 306 can blend the two surfaces such that the intersection 312 is more smooth and continuous than intersections 290 in device 200 which form right angles. The intersections 312 can have an angle between the rear wall and a tangent 317 of the interior surface of the top 310 that is greater than 90 degrees. The intersection 312 may also form a blended radius. It should be noted that this feature of the intersection 312 being more smooth and continuous can be applied to the side wall 304 and top surface intersection 312 and the front surface and top surface intersection 312 and the intersection 312 geometry may vary along the perimeter of the top 310. In other words, it can apply to all or any of the surfaces that connect to the top interior surface.

Further embodiments can include the features described herein, but with the vertical electronic device being rectangular from a top plan view perspective.

Additional embodiments can include the features described herein, but the exterior surface of the top 310 including the access door 314 being characterized as part of the exterior top surface.

Although the illustrative embodiments have been described herein with reference to the accompanying drawings, it is to be understood that the present principles are not limited to those precise embodiments, and that various changes and modifications may be effected therein by one of ordinary skill in the pertinent art without departing from the scope of the present principles. All such changes and modifications are intended to be included within the scope of the present principles as set forth in the appended claims.

It should be understood that the device is an electronic device that contains at least one electronic component 341 generically shown in FIG. 4 which can include a printed a circuit board, a hard drive, a smart card assembly, a tuner, and an antenna, etc.

Also, it is intended that expressions such as “back” and “front” and “vertical” and “horizontal,” as well as other complementary terms are intended to be construed from the perspective of the observer of the figures; and as such, these expression can be interchanged depending upon the direction from which the device is observed.

1. A housing for an electronic device comprising:
a curved top;
a vertical front wall;
a vertical rear wall;
vertical side walls;
at least one electronic component in said housing generating heat during operation; and,
a thermal management system for dissipating said heat.

2. The housing of claim 1, wherein said thermal management system comprises at least one of active or passive component.

3. The housing of claim 1, wherein said thermal management system comprises vents in at least one of said vertical walls.

4. The housing of claim 1, wherein said thermal management system comprises vents in each of said vertical side walls.

5. The housing of claim 3, wherein said at least one vertical wall is disposed at an angle, relative to horizontal, such that for any given one of said vents disposed at a lower level than a vent disposed upwardly adjacent to said one of said lower vents, any of said heat dissipated through said any given lower vent is directed upwardly and away from said upwardly adjacent vent.

6. The housing of claim 4, wherein each of said vertical side walls is disposed at an angle, relative to horizontal, such that for any given one of said vents disposed at a lower level than a vent disposed upwardly adjacent to said one of said lower vents, any of said heat dissipated through said any given lower vent is directed upwardly and away from said upwardly adjacent vent.

7. A vertically oriented set top box, comprising:
a curved top;
a vertical front wall;
a vertical rear wall;
vertical side walls;
at least one electronic component in the vertically oriented set top box generating heat during operation; and,
a thermal management system for dissipating said heat.

8. The vertically oriented set top box of claim 7, wherein said thermal management system comprises vents in at least one of said vertical walls and said at least one vertical wall is disposed at an angle, relative to horizontal, such that for any given one of said vents disposed at a lower level than a vent disposed upwardly adjacent to said one of said lower vents, any of said heat dissipated through said any given lower vent is directed upwardly and away from said upwardly adjacent vent.

9. The vertically oriented set top box of claim 7, wherein said thermal management system comprises vents in each of said vertical side walls and each of said vertical side walls is disposed at an angle, relative to horizontal, such that for any given one of said vents disposed at a lower level than a vent disposed upwardly adjacent to said one of said lower vents, any of said heat dissipated through said any given lower vent is directed upwardly and away from said upwardly adjacent vent.

10. The vertically oriented set top box of claim 7 comprising at least one intersection region between the curved top and at least one of the vertical walls that forms an angle or angles greater than 90 degree on an exterior surface of the curved top and the vertical walls.

11. The vertically oriented set top box of claim 10 wherein the one intersection region is along the entire side of one of the vertical walls.

12. The vertically oriented set top box of claim 7 wherein an exterior surface of the curved top is convex and an interior surface of the curved top is concave.

13. The vertically oriented set top box of claim 12 wherein from a top plan view perspective angles between exterior surfaces of the side vertical walls and the vertical rear wall are acute.

14. The vertically oriented set top box of claim 13 wherein a majority of the curved top is sloped downward the vertical front wall.

15. A vertically oriented set top box comprising:
a curved top;
a vertical front wall;
a vertical rear wall;
vertical side walls; and
at least one heat generating electronic component.

16. The vertically oriented set top box of claim 15 comprising at least one intersection region between the curved top and at least one of the vertical walls forms an angle or angles greater than 90 degree on an exterior surface of the curved top and the vertical walls.

17. The vertically oriented set top box of claim 15 wherein an exterior surface of the curved top is convex and an interior surface of the curved top is concave.

18. The vertically oriented set top box of claim 15 wherein from a top plan view perspective angles between exterior surfaces of the side vertical walls and the vertical rear wall are acute.

19. The vertically oriented set top box of claim 16 wherein a majority of the curved top is sloped downward toward the vertical front wall.

20. The vertically oriented set top box of claim 15 comprising an access door that is part of the curved top, wherein the access door has an exterior surface that is part of an exterior surface of the curved top.

21. The vertically oriented set top box of claim 20 comprising vents positioned over a majority of plan view surface areas of the vertical side walls.
